(19) United States
(12) Patent Application Publication
(10) Pub. No.: US 2025/0392307 A1
(43) Pub. Date: Dec. 25, 2025

(54) REDUCED LEAKAGE TRACKING SWITCH CIRCUIT

(71) Applicant: Altera Corporation, San Jose, CA (US)

(72) Inventors: Yevgeny PERELMAN, Haifa (IL); Zeev TOROKER, Haifa (IL); Tzachi CARBONE, Nofit (IL)

(21) Appl. No.: 19/309,462

(22) Filed: Aug. 25, 2025

(51) Int. Cl. H03K 17/687

(52) U.S. Cl. CPC H03K 17/6871

(57) ABSTRACT

Some examples include tracking switches that may be used as passgates such as for sensing circuit multiplexers. The tracking switches include tracking circuits to provide off-state voltages at inner passgate junction nodes to reduce leakage current in the tracking switch when it is to be off.

### TECHNICAL FIELD

Embodiments relate to the field of semiconductor circuits and in particular to switch circuits formed from transistors.

### BRIEF DESCRIPTION OF THE DRAWINGS

The disclosure may best be understood by referring to the following description and accompanying drawings that are used to illustrate embodiments. In the drawings:

FIG. 1 is a circuit diagram showing a portion of a conventional sensing circuit.

FIG. 2A is a diagram showing a conventional, simple passgate circuit.

FIG. 2B is a diagram showing another type of conventional passgate switch circuit.

FIG. 3 is a diagram showing a tracking switch circuit in accordance with some embodiments.

FIG. 4 is a diagram showing a portion of a sensing circuit for sensing a selected signal in accordance with some embodiments.

FIG. 5A is a diagram showing a test structure for simulating operation of sensor circuits using the different switches described herein.

FIG. 5B is a table showing test signal levels for the test structure of FIG. 5A.

FIG. 5C Illustrates a comparison of current leakage for the three types of passgate switches using the test structure of FIG. 5A.

FIG. 5D illustrates output voltage error for the three types of switches using the test structure of FIG. 5A.

FIG. 6 illustrates an example computing system in accordance with some embodiments.

FIG. 7 illustrates a block diagram of an example processor that may have one or more cores and an integrated memory controller in accordance with some embodiments.

FIG. 8 is a block diagram illustrating a parallel processing computing system 800 configured to implement one or more aspects of the examples described herein.

### DETAILED DESCRIPTION

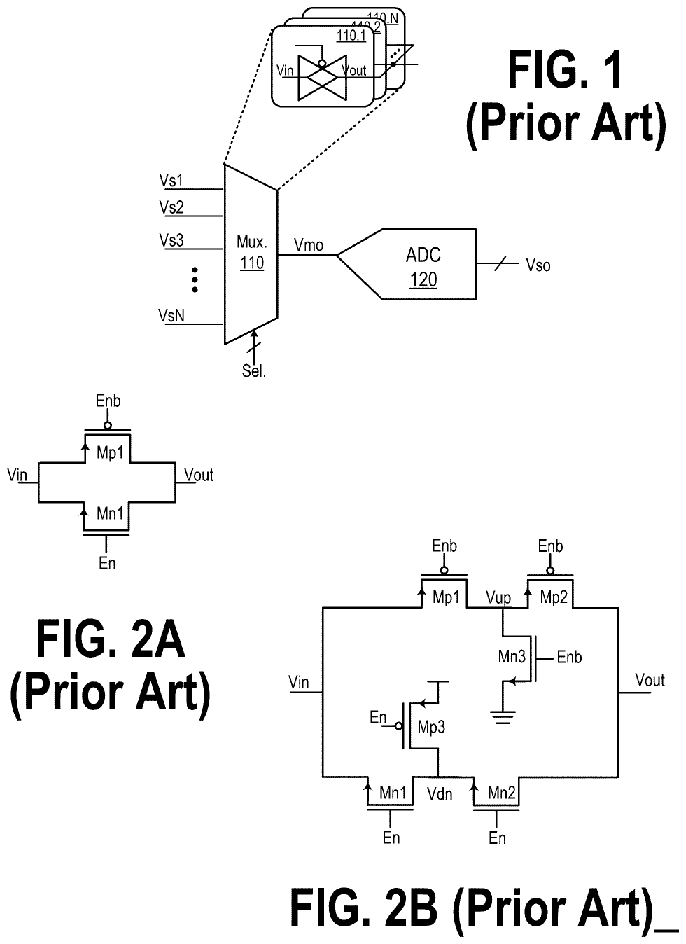

FIG. 1 is a circuit diagram showing a portion of a conventional sensing circuit. For example, such a circuit may be used for selecting and sensing one of several different clock signals in an input/output (IO) interface module. The circuit uses a multiplexer 110 coupled to an analog-to-digital converter (ADC) 120. The multiplexer 120 is formed from N separate pass gate switches (110.1-110.N) coupled together in parallel for passing a selected one of the N inputs (Vs1-VsN) to a multiplexer output (Vmo). From here, the selected signal is digitized and provided at a sense output node (Vso).

With such sense circuits, it is often important to achieve high-sensed signal accuracy. To do this, it is necessary for the sensed signal (Vmo) to be affected as little as possible by leakage from the neighboring pass gate switches that are not selected (turned off). Such high accuracy is particularly important in high-speed input/output (IO) circuits, such as with SerDes applications, e.g., for calibration of phase spacing in high-frequency clocks. Unfortunately, existing pass gate circuits are not adequate for attaining the desired accuracy in many cases.

FIG. 2A is a diagram showing a conventional, simple passgate circuit. It includes a P-type MOS (metal oxide semiconductor) transistor (Mp1) and an N-type MOS transistor (Mn1) with their sources and drains coupled together as indicated. The circuit has a signal input (Vin), a signal output (Vout), and control inputs (complementary inputs En, Enb). When the control signals (En, Enb) are set to Vcc and Vss, respectively, the passgate switch is in an on state. Depending on the input voltage (Vin), either Mn1 or Mp1 operates in the triode region, resulting in Vout being approximately equal to Vin. Conversely, when the control signals (En, Enb) are set to Vss and Vcc, respectively, the passgate switch is turned off. In this state, Vout enters a high-impedance (high-Z) state.

However, even when the passgate is turned off, a current leakage can occur between Vin and Vout, depending on the voltage difference between them. The maximum current leakage occurs when the voltage difference is large (at least 100 mV) and is minimized when the voltage difference is small. With this topology, there is no additional circuit specifically designed to minimize the voltage difference across the switch when it is turned off. As a result, current leakage is sensitive to the voltage difference between Vout and Vin.

When a multiplexer (MUX) is constructed using such a passgate switch, the current leakage may flow to an active switch (in the “on” position). Since the resistance of the switch is finite and the interconnects between Vin and Vout have finite resistance as well, the current leakage can cause a non-negligible IR drop, which leads to a significant voltage difference between Vout and Vin.

FIG. 2B is a diagram showing another conventional passgate switch circuit. The passgate switch circuit here is similar to the simple passgate switch shown in FIG. 1, except that it additionally includes a parking feature to reduce off-state leakage. The switch consists of pass transistors Mp1, Mp2, Mn1, and Mn2, along with parking transistors Mp3 and Mn3, all coupled together as shown. There are junction nodes, Vup, Vdn, at the junctions of coupled together transistors Mp1, Mp2, and MN1, Mn2, respectively. As with the circuit of FIG. 1, the operation of this circuit depends on two control signals (En, Enb). When En is '1 (or Vcc) and Enb is '0 (or Vss), the switch is in the on state, resulting in Vout being approximately equal to Vin. Conversely, when the switch is turned off, with En at '0 and Enb at '1, the transistors Mn3 and Mp3 are activated. This causes junction node Vup to be at OV and Vdn to be at Vcc.

When lower voltage levels are at Vout or Vin, transistors Mp1 and Mp2 exhibit low drain-source leakage, while the primary source of current leakage comes from transistors Mn2 and Mn1. On the other hand, with high supply voltages at Vin or Vout, leakage through Mn1 and Mn2 is minimized, but leakage through Mp2 and Mp1 is at its worst. When Vin or Vout are at mid-level voltages, current leakage arises from both the N and P type transistors.

Compared to the passgate switch circuit of FIG. 1, the overall leakage is reduced, indicating an improvement. However, the leakage can still be significant, particularly when the drain-source voltages are at or near the extremes (e.g., Vcc or Vss). Accordingly, new approaches would be desired.

In some embodiments, a tracking switch with multiple, series-coupled passgate switches and tracking circuits that track input/output states is provided. In some embodiments, such tracking switches can achieve low leakage currents at the input and output ends. When the tracking switch is in an on state, it functions like a traditional pass gate, but when it is turned off, it reduces current leakage by activating tracking circuits that reduce voltage differences across the switch. This serves to decrease the drain-source current leakage effectively.

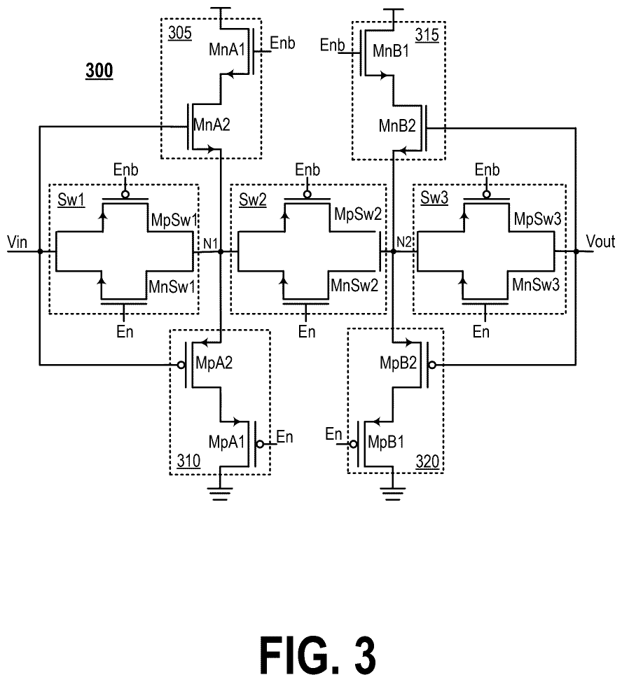

FIG. 3 is a diagram showing a tracking switch circuit in accordance with some embodiments. The tracking switch circuit 300 includes first, second, and third passgate switches (Sw1, Sw2, Sw3), coupled together in series, along with first and second input node tracking circuit legs (305, 310) and first and second output tracking circuit legs (315, 320), all coupled together as shown. The tracking switch has input and output nodes (Vin, Vout), control nodes (En, Enb), and inner junction nodes (N1, N2).

The passgate switches may be implemented with any suitable circuit configuration. In the depicted embodiment, they are formed from coupled pairs of P and N-type MOS transistors, as with simple passgate switch configurations. Other configurations, however, may be used, depending on design considerations. For example, in some embodiments, they could be implemented with single transistors or with other types of analog switch structures.

Likewise, tracking circuits may be implemented with any suitable circuit to provide a voltage at an inner junction node based on an input or output voltage level of a tracking switch. In the depicted example, tracking circuit legs, formed from series-coupled transistors, are used, but it should be appreciated that other circuits, e.g., using more than two transistors, could be used. In addition, while in the depicted example, tracking circuits are used for junction nodes based on both the input and output nodes, other embodiments may use only input or output tracking circuits, depending on design needs and resources.

With the depicted circuit, the first input node tracking circuit leg 305 includes control transistor MnA1 and tracking transistor MnA2 coupled together in series between a high supply reference (Vcc) and the first junction node (N1). The second input node tracking circuit 310 includes control transistor MpA1 and tracking transistor MpA2 coupled together in series between a low supply reference (Vss) and the first junction node (N1). The first output node tracking circuit 315 includes control transistor MnB1 and tracking transistor MnB2 coupled together in series between Vcc and the second junction node (N2). The second output node tracking circuit 320 includes control transistor MpB1 and tracking transistor MpB2 coupled together in series between Vss and the second junction node (N2).

The first passgate switch (Sw1) has an input, which serves as the input (Vin) for the tracking switch. It also has an output that is coupled to the input of the second passgate switch (Sw2) at the first junction node (N1). Likewise, the third passgate switch (Sw3) has an output that serves as the tracking switch output (Vout) and an input that is coupled to the output of the second passgate switch (Sw2) at the second junction node (N2).

The tracking switch has two modes of operation. In an on mode, the control signals (En, Enb) are set to Vcc and Vss, respectively. When this occurs, the passgate switches (SW1, SW2, SW3) are conducting. During this time, the tracking circuit control transistors (MnA1, MpA1, MnB1, and MpB1) are turned off. As a result, Vout closely follows Vin, with a minor voltage drop across the passgates due to the resistances of the passgate switches (SW1, SW2, SW3).

In the off state, the passgate switches (Sw1, Sw2, Sw3) are turned off, while the control switches (MnA1, MnB1, MpA1, MpB1) are activated. During this state, the overall tracking switch is in a high-Z mode.

Regarding the input side, when Vin is close to the high supply reference (Vcc), tracking transistor MnA2 exhibits low resistance while tracking transistor MpA2 exhibits high resistance, causing the first (input side) junction node (N1) to be close to Vcc. Conversely, when Vin is near Vss, MnA2 has high resistance, and MpA2 has relatively low resistance, resulting in N1 being approximately 0. At intermediate voltages such as around Vcc/2, both MnA2 and MpA2 conduct similarly with comparable resistances, and N1 is approximately Vcc/2. Thus, when the tracking switch is to be off, N1 tracks the input voltage (Vin), which helps to minimize the drain/source voltage drop across the first switch (Sw1), reducing overall tracking switch leakage.

The output side of the circuit works similarly, but with junction node N2 tracking the output voltage (Vout) to minimize current leakage at the N2 junction node. Therefore, the leakage from the middle switch (Sw2) does not meaningfully contribute to voltage error on either the input (Vin) or output (Vout) sides of the circuit.

Accurate DC voltage measurements are essential for precise calibration processes. For instance, calibration precision can be crucial in high-speed clock circuits that use multiple clock phases. Additionally, having precise voltage measurements can help reduce calibration convergence times, as it enables the process to depend on the actual measurements.

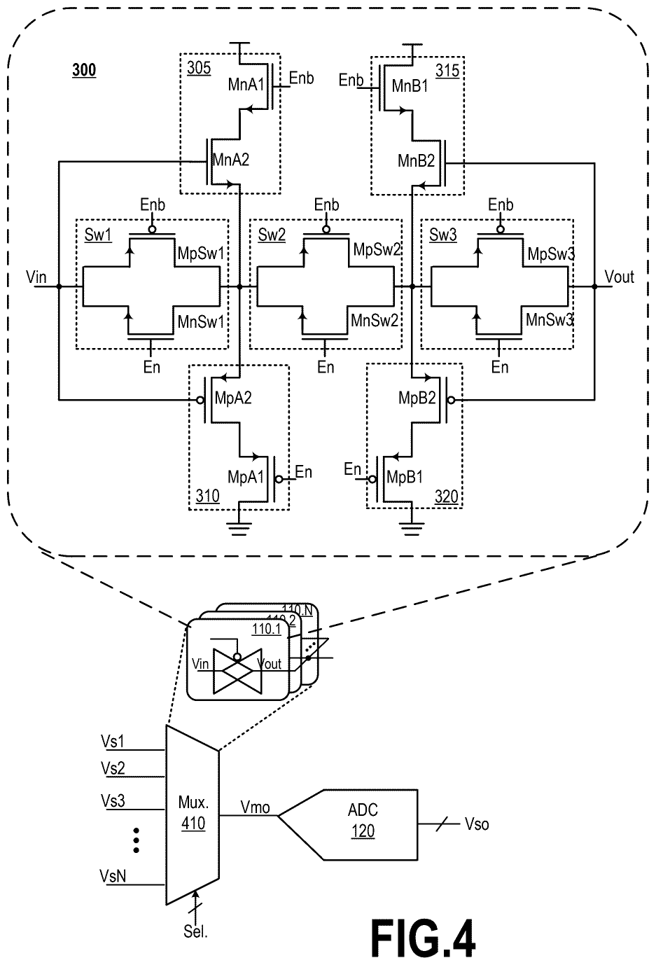

FIG. 4 is a diagram showing a portion of a sensing circuit for sensing a selected signal in accordance with some embodiments. The circuit includes a multiplexer 410 with N input signals (Vs1-VsN) coupled to an ADC 120 for providing a digital version (Vso) of a selected one of the input voltage signals from the multiplexer analog output node (Vmo). This circuit portion may, for example, be implemented in a high-speed clock that requires calibration. The output (Vmo) from the multiplexer may be a DC-like signal sent to the input of the ADC 120. The multiplexer includes N different tracking passgate switches 300. For example, in some embodiments, tracking switches such as the tracking switch 300 of FIG. 3 may be used. With their reduced leakage, the tracking switches can facilitate accurate signal sensing, even when multiple tracking switches are coupled together in parallel.

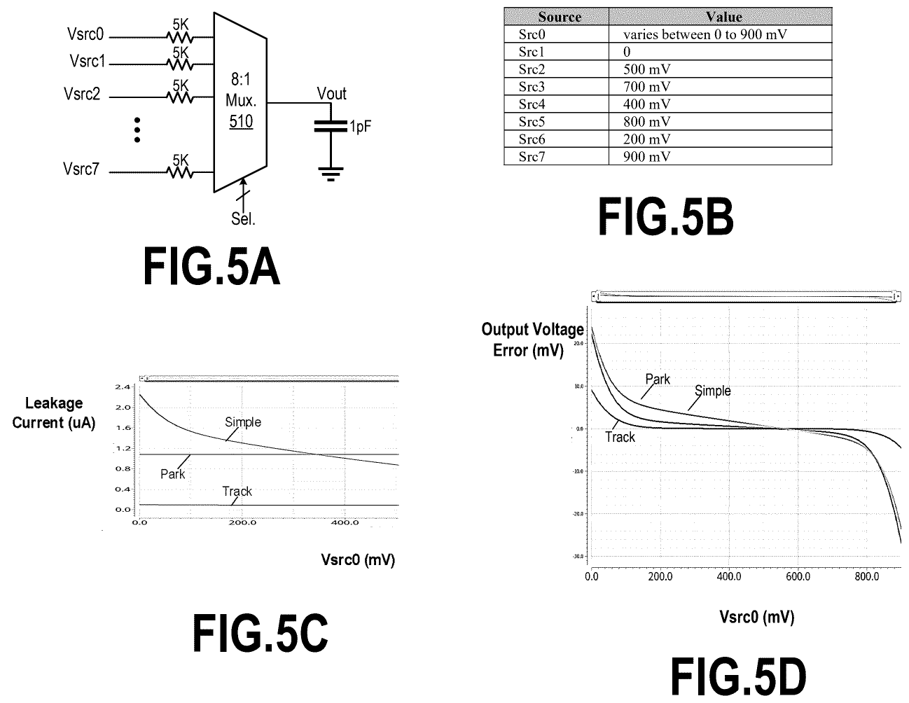

FIG. 5A is a diagram showing a test structure for simulating the operation of sensor circuits using the different switches described herein. The simulation tested operating characteristics for an 8:1 multiplexer 510 formed from tracking switches such as the tracking switch 300 of FIG. 3. Eight test signal sources (Vsrc0-Vsrc7) were coupled to the multiplexer inputs through 5 KΩ resistors, and an output (Vout) was measured off of a 1 pF capacitance. As illustrated, the multiplexer represents part of the DC path through which the sensing signal must pass before reaching the output, e.g., which may serve as an input to an ADC or a comparator. The capacitor load represents, for example, a comparator slicer input load, while the resistors represent layout interconnect resistance. The resistor may also be part of a low-pass filter required before the sensing signal reaches the comparator slicer.

With this test setup, three separate runs were performed with the multiplexer switches implemented with a simple pass gate switch, a parking switch, and a tracking switch with switches such as the circuits from FIGS. 1, 2, and 3, respectively. With these tests, only the first signal (Vrsc0) was selected for conduction to the output (Vout) with different input voltages applied to the eight test inputs (Vsrc0-Vsrc7) as indicated in the table of FIG. 5B.

With this test, the current leakage when the multiplexer is off, along with the sensed output voltage error for the Vsrc0 test input, was measured. The current leakage is measured when the switch is off, indicating that it is disabled. The output voltage error is the difference between the output voltage at net Vout and the input voltage Vsrc0.

FIG. 5C illustrates a comparison of current leakage for the three types of passgate switches. The results show that the simple pass gate has the highest current leakage, peaking at approximately 2.25 uA when the input voltage reaches 0 mV. In contrast, the parking switch exhibits a nearly constant leakage current of 1 uA across varying input voltages. It can be seen, however, that the tracking switch demonstrates a significantly lower leakage current of 0.1 uA under the same conditions.

FIG. 5D illustrates output voltage errors for the three test structure switch types. Here, the test error is defined as Vout-Vsrc0, where Vsrc0 represents the input voltage and Vout is the measured signal at the output of the multiplexer. The input voltage Vsrc0 varies between 0 mV and 900 mV. The data shows that for Vsrc0=0 mV, the error voltage deviation reach approximately 23 mV for the simple passgate switch. In contrast, the parking switch can achieve an error deviation of up to 22 mV. Notably, the switch with the tracking voltage exhibits a much smaller error, calculated at only up to 9 mV.

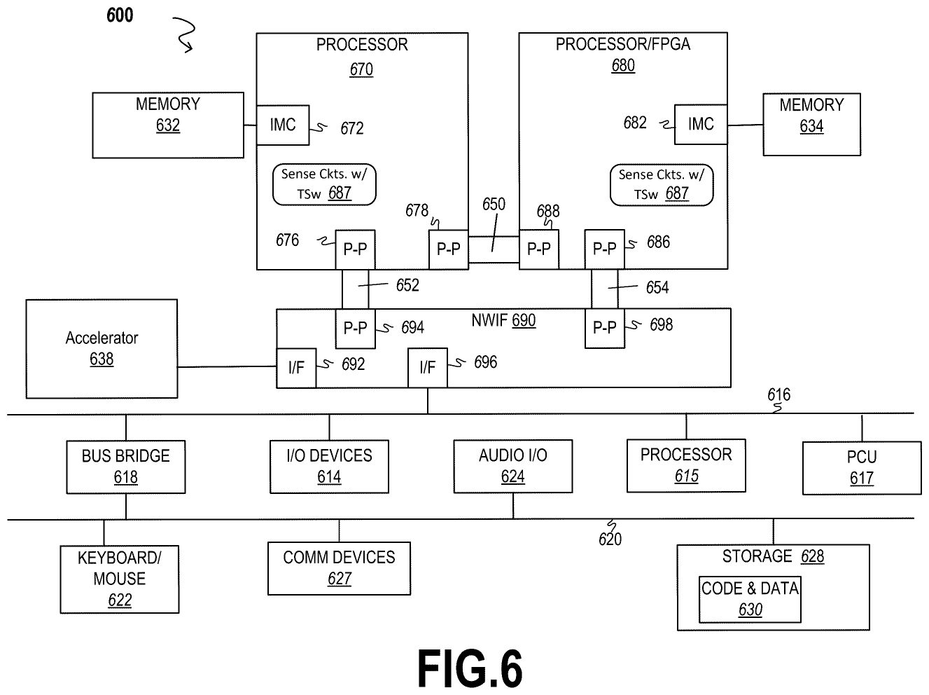

FIG. 6 illustrates an example computing system in accordance with some embodiments. Multiprocessor system 600 is an interfaced system and includes a plurality of processors including a first processor 670 and a second processor 680 coupled via an interface 650 such as a point-to-point (P-P) interconnect, a fabric, and/or bus. In some examples, the first processor 670 and the second processor 680 are homogeneous. In some examples, first processor 670 and the second processor 680 are heterogenous. Though the example system 600 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 670 and 680 are shown including integrated memory controller (IMC) circuitry 672 and 682, respectively. Processor 670 also includes interface circuits 676 and 678, along with core sets. Similarly, second processor 680 includes interface circuits 686 and 688, along with a core set as well. The processors also may include a sensing circuit with a tracking switch (TSw) 687, in accordance with the tracking switch circuits described herein.

A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 670, 680 may exchange information via the interface 650 using interface circuits 678, 688. IMCs 672 and 682 couple the processors 670, 680 to respective memories, namely a memory 632 and a memory 634, which may be portions of main memory locally attached to the respective processors.

Processors 670, 680 may each exchange information with a network interface (NW I/F) 690 via individual interfaces 652, 654 using interface circuits 676, 694, 686, 698. The network interface 690 (e.g., one or more of an interconnect, bus, and/or fabric, and in some examples is a chipset) may optionally exchange information with a coprocessor 638 via an interface circuit 692. In some examples, the coprocessor 638 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 670, 680 or outside of both processors, yet connected with the processors via an interface such as P-P interconnect, such that either or both processors' local cache information may be stored in the shared cache if a processor is placed into a low power mode.

Network interface 690 may be coupled to a first interface 616 via interface circuit 696. In some examples, first interface 616 may be an interface such as a Peripheral Component Interconnect (PCI) interconnect, a PCI Express interconnect, or another I/O interconnect. In some examples, first interface 616 is coupled to a power control unit (PCU) 617, which may include circuitry, software, and/or firmware to perform power management operations with regard to the processors 670, 680 and/or co-processor 638. PCU 617 provides control information to one or more voltage regulators (not shown) to cause the voltage regulator(s) to generate the appropriate regulated voltage(s). PCU 617 also provides control information to control the operating voltage generated. In various examples, PCU 617 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 617 is illustrated as being present as logic separate from the processor 670 and/or processor 680. In other cases, PCU 617 may execute on a given one or more of cores (not shown) of processor 670 or 680. In some cases, PCU 617 may be implemented as a microcontroller (dedicated or general-purpose) or other control logic configured to execute its own dedicated power management code, sometimes referred to as P-code. In yet other examples, power management operations to be performed by PCU 617 may be implemented externally to a processor, such as by way of a separate power management integrated circuit (PMIC) or another component external to the processor. In yet other examples, power management operations to be performed by PCU 617 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 614 may be coupled to first interface 616, along with a bus bridge 618 which couples first interface 616 to a second interface 620. In some examples, one or more additional processor(s) 615, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 616. In some examples, second interface 620 may be a low pin count (LPC) interface. Various devices may be coupled to second interface 620 including, for example, a keyboard and/or mouse 622, communication devices 627 and storage circuitry 628. Storage circuitry 628 may be one or more non-transitory machine-readable storage media as described below, such as a disk drive or other mass storage device which may include instructions/code and data 630 and may implement the storage in some examples. Further, an audio I/O 624 may be coupled to second interface 620. Note that other architectures than the point-to-point architecture described above are possible. For example, instead of the point-to-point architecture, a system such as multiprocessor system 600 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

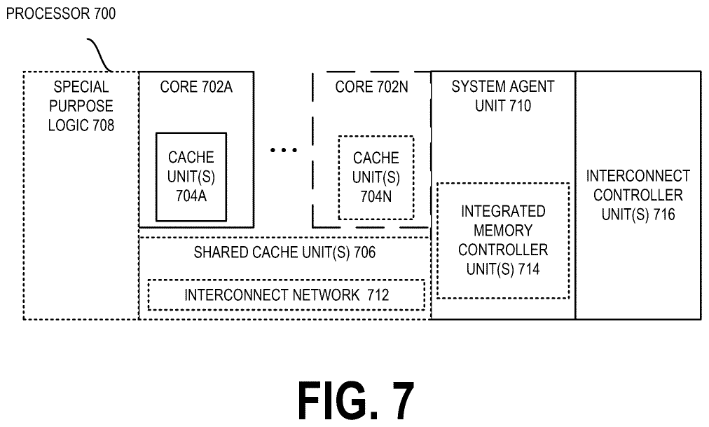

FIG. 7 illustrates a block diagram of an example processor that may have one or more cores and an integrated memory controller in accordance with some embodiments. The solid lined boxes illustrate a processor and/or SoC 700 with a single core 702(A), system agent unit circuitry 710, and a set of one or more interface controller unit(s) circuitry 716, while the optional addition of the dashed lined boxes illustrates an alternative processor and/or SoC 700 with multiple cores 702(A)-(N), a set of one or more integrated memory controller unit(s) circuitry 714 in the system agent unit circuitry 710, and special purpose logic 708, as well as a set of one or more interface controller unit(s) circuitry 716. Note that the processor and/or SoC 700 may be one of the processors 670 or 680, or co-processor 638 or 615 of FIG. 6.

Thus, different implementations of the processor and/or SoC 700 may include: 1) a CPU with the special purpose logic 708 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like (which may include one or more cores, not shown), and the cores 702(A)-(N) being one or more general purpose cores (e.g., general purpose in-order cores, general purpose out-of-order cores, or a combination of the two); 2) a co-processor with the cores 702(A)-(N) being a large number of special purpose cores intended primarily for graphics and/or scientific (throughput); and 3) a co-processor with the cores 702(A)-(N) being a large number of general purpose in-order cores. Thus, the processor and/or SoC 700 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 700 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 704(A)-(N) within the cores 702(A)-(N), a set of one or more shared cache unit(s) circuitry 706, and external memory (not shown) coupled to the set of integrated memory controller unit(s) circuitry 714. The set of one or more shared cache unit(s) circuitry 706 may include one or more mid-level caches, such as level 2 (L2), level 3 (L3), level 4 (L4), or other levels of cache, such as a last level cache (LLC), and/or combinations thereof. While in some examples interface network circuitry 712 (e.g., a ring interconnect) interfaces the special purpose logic 708 (e.g., integrated graphics logic), the set of shared cache unit(s) circuitry 706, and the system agent unit circuitry 710, alternative examples use any number of well-known techniques for interfacing such units. In some examples, coherency is maintained between one or more of the shared cache unit(s) circuitry 706 and cores 702(A)-(N). In some examples, interface controller unit(s) circuitry 716 couple the cores 702(A)-(N) to one or more other devices 718 such as one or more I/O devices, storage, one or more communication devices (e.g., wireless networking, wired networking, etc.), etc.

In some examples, one or more of the cores 702(A)-(N) are capable of multi-threading. The system agent unit circuitry 710 includes those components coordinating and operating cores 702(A)-(N). The system agent unit circuitry 710 may include, for example, power control unit (PCU) circuitry and/or display unit circuitry (not shown). The PCU may be or may include logic and components needed for regulating the power state of the cores 702(A)-(N) and/or the special purpose logic 708 (e.g., integrated graphics logic). The display unit circuitry is for driving one or more externally connected displays.

The cores 702(A)-(N) may be homogenous in terms of instruction set architecture (ISA). Alternatively, the cores 702(A)-(N) may be heterogeneous in terms of ISA; that is, a subset of the cores 702(A)-(N) may be capable of executing an ISA, while other cores may be capable of executing only a subset of that ISA or another ISA.

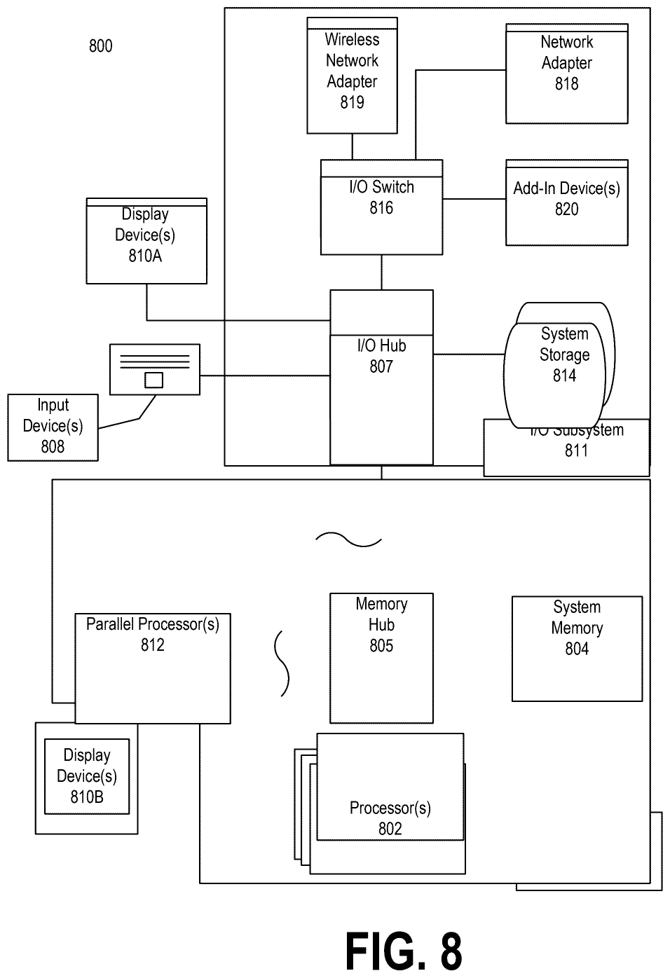

FIG. 8 is a block diagram illustrating a parallel processing computing system 800 configured to implement one or more aspects of the examples described herein. The computing system 800 includes a processing subsystem 801 having one or more processor(s) 802 and a system memory 804 communicating via an interconnection path that may include a memory hub 805. The memory hub 805 may be a separate component within a chipset component or may be integrated within the one or more processor(s) 802. The memory hub 805 couples with an I/O subsystem 811 via a communication link 806. The I/O subsystem 811 includes an I/O hub 807 that can enable the computing system 800 to receive input from one or more input device(s) 808. Additionally, the I/O hub 807 can enable a display controller, which may be included in the one or more processor(s) 802, to provide outputs to one or more display device(s) 810A. In some examples the one or more display device(s) 810A coupled with the I/O hub 807 can include a local, internal, or embedded display device.

The processing subsystem 801, for example, includes one or more parallel processor(s) 812 coupled to memory hub 805 via a bus or communication link 813. The communication link 813 may be one of any number of standards-based communication link technologies or protocols, such as, but not limited to PCI Express, or may be a vendor specific communications interface or communications fabric. The one or more parallel processor(s) 812 may form a computationally focused parallel or vector processing system that can include a large number of processing cores and/or processing clusters, such as a many integrated core (MIC) processor. For example, the one or more parallel processor(s) 812 form a graphics processing subsystem that can output pixels to one of the one or more display device(s) 810A coupled via the I/O hub 807. The one or more parallel processor(s) 812 can also include a display controller and display interface (not shown) to enable a direct connection to one or more display device(s) 810B.

Within the I/O subsystem 811, a system storage unit 814 can connect to the I/O hub 807 to provide a storage mechanism for the computing system 800. An I/O switch 816 can be used to provide an interface mechanism to enable connections between the I/O hub 807 and other components, such as a network adapter 818 and/or wireless network adapter 819 that may be integrated into the platform, and various other devices that can be added via one or more add-in device(s) 820. The add-in device(s) 820 may also include, for example, one or more external graphics processor devices, graphics cards, and/or compute accelerators. The network adapter 818 can be an Ethernet adapter or another wired network adapter. The wireless network adapter 819 can include one or more of a Wi-Fi, Bluetooth, near field communication (NFC), or other network device that includes one or more wireless radios.

The computing system 800 can include other components not explicitly shown, including USB or other port connections, optical storage drives, video capture devices, and the like, which may also be connected to the I/O hub 807. Communication paths interconnecting the various components in FIG. 8 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL.mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (ROCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 812 may incorporate circuitry optimized for graphics and video processing, including, for example, video output circuitry, and constitutes a graphics processing unit (GPU). Alternatively or additionally, the one or more parallel processor(s) 812 can incorporate circuitry optimized for general purpose processing, while preserving the underlying computational architecture, described in greater detail herein. Components of the computing system 800 may be integrated with one or more other system elements on a single integrated circuit. For example, the one or more parallel processor(s) 812, memory hub 805, processor(s) 802, and I/O hub 807 can be integrated into a system on chip (SoC) integrated circuit. Alternatively, the components of the computing system 800 can be integrated into a single package to form a system in package (SIP) configuration. In some examples at least a portion of the components of the computing system 800 can be integrated into a multi-chip module (MCM), which can be interconnected with other multi-chip modules into a modular computing system.

It will be appreciated that the computing system 800 shown herein is illustrative and that variations and modifications are possible. The connection topology, including the number and arrangement of bridges, the number of processor(s) 802, and the number of parallel processor(s) 812, may be modified as desired. For instance, system memory 804 can be connected to the processor(s) 802 directly rather than through a bridge, while other devices communicate with system memory 804 via the memory hub 805 and the processor(s) 802. In other alternative topologies, the parallel processor(s) 812 are connected to the I/O hub 807 or directly to one of the one or more processor(s) 802, rather than to the memory hub 805. In other examples, the I/O hub 807 and memory hub 805 may be integrated into a single chip. It is also possible that two or more sets of processor(s) 802 are attached via multiple sockets, which can couple with two or more instances of the parallel processor(s) 812.

Some of the particular components shown herein are optional and may not be included in all implementations of the computing system 800. For example, any number of add-in cards or peripherals may be supported, or some components may be eliminated. Furthermore, some architectures may use different terminology for components similar to those illustrated in FIG. 8. For example, the memory hub 805 may be referred to as a Northbridge in some architectures, while the I/O hub 807 may be referred to as a Southbridge.

Illustrative examples of the technologies disclosed herein are provided below. An embodiment of the technologies may include any one or more, and any compatible combination of, the examples described below.

Example 1 is a tracking switch circuit that includes passgate switches and tracking circuits. There is first, second, and third passgate switches coupled together in series. The first passgate switch is coupled to the second passgate switch at a first junction node, and the second passgate switch is coupled to the third passgate switch at a second junction node. The first passgate switch includes an input for the tracking switch, and the third passgate switch consists of an output for the tracking switch. The tracking switch also includes a first input tracking circuit leg that is coupled to the tracking switch input, a high supply reference, and the first junction node, and a second input tracking circuit leg that is coupled to the tracking switch input, a low supply reference, and the first junction node.

Example 2 includes the subject matter of Example 1, and comprises a first output tracking circuit leg coupled to the tracking switch output, the high supply reference, and the second junction node, and a second output tracking circuit leg coupled to the tracking switch output, the low supply reference, and the second junction node.

Example 3 includes the subject matter of any of examples 1-2, and wherein the first, second, and third passgate switches are each formed from a parallel-coupled P-type and N-type transistor.

Example 4 includes the subject matter of any of examples 1-3, and wherein at least one of the first input and first output tracking circuit legs include series-coupled N-type transistors.

Example 5 includes the subject matter of any of examples 1-4, and wherein at least one of the second input and second output tracking circuit legs includes series-coupled P-type transistors.

Example 6 includes the subject matter of any of examples 1-5, and wherein the first input tracking circuit leg includes first and second series-coupled transistors with the first transistor including a gate coupled to a first control node and the second transistor including a gate coupled to the tracking switch input.

Example 7 includes the subject matter of any of examples 1-6, and wherein the second input tracking circuit leg includes third and fourth series-coupled transistors with the third transistor including a gate coupled to a second control node and the fourth transistor including a gate coupled to the tracking switch input.

Example 8 is an integrated circuit package that includes a sense circuit with a multiplexer including a plurality of tracking switch circuits in accordance with the tracking subject matter from any of examples 1-7.

Example 9 is a sensing circuit that includes a plurality of signal input nodes and a plurality of tracking switches. The tracking switches include tracking switch input nodes coupled to the plurality of signal input nodes and tracking switch output nodes coupled to a common output node. The tracking switches include an input tracking circuit coupled to a first inner junction node and an output tracking circuit coupled to a second inner junction node.

Example 10 includes the subject matter of example 9, and wherein the tracking switches include a first passgate coupled to a second passgate at the first inner junction node.

Example 11 includes the subject matter of any of examples 9-10, and wherein the tracking switches include a third passgate coupled to the second passgate at the second inner junction node.

Example 12 includes the subject matter of any of examples 9-11, and wherein for the tracking switches, the input tracking circuit comprises a first input tracking leg coupled between a high supply reference node and the first inner junction node and a second input tracking leg coupled between a low supply reference node and the first inner junction node.

Example 13 includes the subject matter of any of examples 9-12, and wherein the first input tracking leg includes series coupled N-type transistors.

Example 14 includes the subject matter of any of examples 9-13, and wherein the second input tracking leg includes series coupled P-type transistors.

Example 15 includes the subject matter of any of examples 9-14, and wherein for the tracking switches, the output tracking circuit comprises a first output tracking leg coupled between the high supply reference node and the second inner junction node and a second output tracking leg coupled between the low supply reference node and the second inner junction node.

Example 16 is an integrated circuit package that includes a sensing circuit in accordance with the subject matter of any of examples 9-15.

Example 17 is a process of making a tracking switch circuit. The process includes (1) coupling passgates together in series between an input node and an output node, the passgates including a first inner junction node and a second inner junction node, (2) coupling an input tracking circuit to the first inner junction node, and (3) coupling an output tracking circuit to the second inner junction node.

Example 18 includes the subject matter of example 17, and wherein the input tracking circuit comprises a first input tracking leg coupled between a high supply reference node and the first inner junction node and a second input tracking leg coupled between a low supply reference node and the first inner junction node.

Example 19 includes the subject matter of any of examples 17-18, and wherein the output tracking circuit comprises a first output tracking leg coupled between the high supply reference node and the second inner junction node and a second output tracking leg coupled between the low supply reference node and the second inner junction node.

Example 20 includes the subject matter of any of examples 17-19, and further comprising making a sensing circuit in an integrated circuit package from the tracking switch.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors.

In the drawings of the embodiments, signals are represented with lines. Some lines may appear different from others, for example, thicker or hatched, to distinguish from other depicted signals for ease of understanding. Along these lines, some signal lines may have arrows at one or more ends, to indicate a primary direction of information flow. However, such indications are not intended to be limiting. Rather, lines are used in connection with one or more exemplary embodiments in a given figure to facilitate easier understanding of concepts embodied in block, circuit, and/or flow diagrams. Any represented signal, as dictated by design needs or preferences, may actually comprise one or more signals that may travel in either direction and may be implemented with any suitable type of signal scheme, e.g., analog, digital, wired, wireless, upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, they may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. A tracking switch circuit, comprising:
first, second, and third passgate switches coupled together in series, wherein the first passgate switch is coupled to the second passgate switch at a first junction node, and the second passgate switch is coupled to the third passgate switch at a second junction node, the first passgate switch including an input for the tracking switch, and the third passgate switch including an output for the tracking switch;
a first input tracking circuit leg coupled to the tracking switch input, a high supply reference, and the first junction node; and
a second input tracking circuit leg coupled to the tracking switch input, a low supply reference, and the first junction node.

2. The tracking switch circuit of claim 1, comprising:
a first output tracking circuit leg coupled to the tracking switch output, the high supply reference, and the second junction node, and
a second output tracking circuit leg coupled to the tracking switch output, the low supply reference, and the second junction node.

3. The tracking switch circuit of claim 1, wherein the first, second, and third passgate switches are each formed from a parallel-coupled P-type and N-type transistor.

4. The tracking switch circuit of claim 2, wherein at least one of the first input and first output tracking circuit legs includes series-coupled N-type transistors.

5. The tracking switch circuit of claim 2, wherein at least one of the second input and second output tracking circuit legs includes series-coupled P-type transistors.

6. The tracking switch circuit of claim 1, wherein the first input tracking circuit leg includes first and second series-coupled transistors with the first transistor including a gate coupled to a first control node and the second transistor including a gate coupled to the tracking switch input.

7. The tracking switch circuit of claim 6, wherein the second input tracking circuit leg includes third and fourth series-coupled transistors with the third transistor including a gate coupled to a second control node and the fourth transistor including a gate coupled to the tracking switch input.

8. An integrated circuit package including a sense circuit with a multiplexer including a plurality of tracking switch circuits in accordance with the tracking switch circuit of claim 1.

9. A sensing circuit, comprising:
a plurality of signal input nodes; and
a plurality of tracking switches including tracking switch input nodes coupled to the plurality of signal input nodes and tracking switch output nodes coupled to a common output node, wherein the tracking switches include an input tracking circuit coupled to a first inner junction node and an output tracking circuit coupled to a second inner junction node.

10. The sensing circuit of claim 9, wherein the tracking switches include a first passgate coupled to a second passgate at the first inner junction node.

11. The sensing circuit of claim 10, wherein the tracking switches include a third passgate coupled to the second passgate at the second inner junction node.

12. The sensing circuit of claim 9, wherein for the tracking switches, the input tracking circuit comprises a first input tracking leg coupled between a high supply reference node and the first inner junction node and a second input tracking leg coupled between a low supply reference node and the first inner junction node.

13. The sensing circuit of claim 12, wherein the first input tracking leg includes series coupled N-type transistors.

14. The sensing circuit of claim 13, wherein the second input tracking leg includes series coupled P-type transistors.

15. The sensing circuit of claim 12, wherein for the tracking switches, the output tracking circuit comprises a first output tracking leg coupled between the high supply reference node and the second inner junction node and a second output tracking leg coupled between the low supply reference node and the second inner junction node.

16. An integrated circuit package including a sensing circuit in accordance with the sensing circuit as recited in claim 9.

17. A process of making a tracking switch circuit, comprising:
coupling passgates together in series between an input node and an output node, the passgates including a first inner junction node and a second inner junction node;
coupling an input tracking circuit to the first inner junction node; and
coupling an output tracking circuit to the second inner junction node.

18. The process of claim 17, wherein the input tracking circuit comprises a first input tracking leg coupled between a high supply reference node and the first inner junction node and a second input tracking leg coupled between a low supply reference node and the first inner junction node.

19. The process of claim 18, wherein the output tracking circuit comprises a first output tracking leg coupled between the high supply reference node and the second inner junction node and a second output tracking leg coupled between the low supply reference node and the second inner junction node.

20. The process of claim 17, further comprising making a sensing circuit in an integrated circuit package from the tracking switch.
